(19) United States
(12) Patent Application Publication
(10) Pub. No.: US 2010/0288344 A1
(43) Pub. Date: Nov. 18, 2010

(54) METHODS AND APPARATUS FOR WAVELENGTH CONVERSION IN SOLAR CELLS AND SOLAR CELL COVERS

(75) Inventor: Mark B. Spitzer, Sharon, MA (US)

Correspondence Address: DALY, CROWLEY, MOFFORD & DURKEE, LLP, SUITE 301A, 354A TURNPIKE STREET, CANTON, MA, 02021-2714, US

(73) Assignee: PHOTONIC GLASS CORPORATION, Sharon, MA (US)

(21) Appl. No.: 12/778,365

(22) Filed: May 12, 2010

Related U.S. Application Data
(60) Provisional application No. 61/178,098, filed on May 14, 2009.

(51) Int. Cl. H01L 31/0352; H01L 31/0232; H01L 31/0248

(52) U.S. Cl. 136/255; 136/259; 136/252; 257/E31.033; 257/E31.127; 257/E31.002

(57) ABSTRACT

Method and apparatus for providing a photon conversion device including a first layer for photon absorption, and a second layer for photon emission wherein the first layer is separate from the second layer, wherein the first and second layers enable excited electrons and holes to move from the first layer to the second layer and recombine in the second layer.

### CROSS-REFERENCE TO RELATED APPLICATIONS

The present application claims the benefit of U.S. Provisional Patent Application No. 61/178,098, filed on May 14, 2009, which is incorporated herein by reference.

### FIELD OF THE INVENTION

The present invention relates to the improvement of energy conversion efficiency of solar cells.

### BACKGROUND

Conventional photovoltaic cells made from a single absorbing semiconductor are limited in efficiency to less than 30% and typically, the practical efficiency limits of flat plate solar modules made from silicon are limited to the range of 23% to 25%. The fundamental energy loss mechanisms in single-absorber cells that are used in both concentrator and flat plate modules arise from the mismatch between the solar spectrum and the absorption spectrum of the semiconductor, largely determined by the optical band gap, E_{G}, of the semiconductor.

Tandem solar cells are made from two or more absorbing semiconductors and address this limitation by stacking cells with different optical band gaps in series. By using two or more different absorbing semiconductors, tandem cells can attain higher peak efficiency than single junction cells. However, tandem solar cells are expensive, and have other conversion efficiency limitations that occur as the spectrum changes during the day. It would be desirable to improve efficiency economically in flat plate modules and concentrator modules.

FIG. 1 illustrates a prior art solar cell formed from a semiconductor 1. Examples of absorbing semiconductors are silicon, gallium arsenide, and cadmium telluride. As is well known in the art, a semiconductor is characterized by its energy band gap referred to as E_{G}. Referring to FIG. 1, a p/n junction 2 is used to separate photogenerated pairs (electrons and holes, or “e-h pairs”). Electrical contact is made by a back contact 3 and a front contact grid, which usually has a plurality of interconnected contact lines 4. Reflectance of the absorbing semiconductor 1 is usually reduced by an antireflection coating 5 applied to the front surface upon which light rays are incident. In FIG. 1, light rays 6, 7, 8 represent three spectral bands in the incident solar flux.

The three solar light rays 6,7,8 represent all of the solar photons incident on the solar cell. Ray 6 comprises photons each with energy greater than E_{G}. Ray 7 comprises photons with energy approximately equal to E_{G}. Ray 8 comprises photons with energy less than E_{G}. It should be understood that solar photons generally are incident uniformly on the surface of the solar cell independent of energy, and this representation is for illustrative purposes.

The absorption of photons in semiconductor 1 depends highly on the energy; thus, it is appropriate to consider photons in three groups as represented by rays 6, 7, and 8. The spectral bands associated with rays 6, 7, and 8 depend on the value of E_{G} of the absorbing semiconductor. For silicon at room temperature, ray 6 corresponds to photons with wavelength shorter than 1110 nm; ray 7 corresponds to photons with wavelength approximately equal to 1110 nm, and ray 8 corresponds to photons with wavelength greater than 1110 nm.

The absorption process in a conventional solar cell may be better understood by reference to the simplified energy band diagram shown in FIG. 2 which depicts electron energy on the ordinate (“y”) axis and depth into the semiconductor 1 (measured from the front surface of semiconductor 1) on the abscissa (“x”) axis. Electrons associated with optical absorption and emission occupy energy states within the semiconductor, and the states occur in bands called the conduction band and the valence band. Electrons in the conduction band have higher energy than electrons in the valence band. The conduction band has a minimum energy 10 and the valence band has a maximum energy 20. The difference in these energies is the energy band gap E_{G}. Electron energy greater than the valence band maximum energy 20 and less than the conduction band minimum energy 10 is forbidden in a pure semiconductor.

The fundamental photon absorption process in a semiconductor comprises the excitation by a photon of an electron from a state in the valence band to a state in the conduction band. The smallest photon energy for which this process can occur corresponds to an event that raises the energy of an electron at the valence band state of maximum energy 20 to the conduction band state of minimum energy 10, and energy less than this difference is insufficient for absorption. In other words, photons with energy less than E_{G} cannot excite an electron from the valence band to the conduction band, and such photons are not usefully absorbed. In FIGS. 1 and 2, we show ray 8 comprising photons with energy less than E_{G} as passing through the material without absorption. In a conventional photovoltaic cell the energy of such photons is lost and we call this “non-absorption loss.”

With reference to FIG. 3, a photon in ray 6 having energy greater than E_{G} is absorbed by exciting an electron 31 from the valence band to the conduction band, leaving a hole 32 in the valence band. The photon provides energy to the electron that is greater than E_{G} and thus the resultant energy 30 of the excited electron is greater than the conduction band minimum energy 10. Almost immediately this electron loses this excess energy to heat (lattice excitation) 40 as it relaxes to the conduction band minimum energy 10. The energy provided by the photon that is in excess of E_{G} is lost. We call this “thermalization loss.” The thermalization and non-absorption losses are both zero only if the photon energy is equal to E_{G}.

In a single-absorber solar cell, the amount of energy lost to (i) non-absorption and (ii) thermallization depends on the band gap E_{G} of the semiconductor from which the solar cell is made, and the incident solar spectrum. In Table 1 we provide the result of a calculation of these losses for the case of a prior art silicon solar cell, assuming an incident spectrum with a total incident power of 100 mW/cm². Together these losses account for 51 mW/cm² that is therefore unavailable for conversion to electricity by a prior art silicon solar cell. A loss of a similar magnitude would result from the use of any single semiconductor in a solar cell.

TABLE 1
Summary of Power Loss in Silicon Solar Cells

| Power source or loss | Power (mW/cm²) |
|---|---|
| Total Incident Power (insolation) | 100 (AM1.5) |
| Power Lost to Thermalization (E > E_{G}) | −32 |
| Power Lost to non-absorption (E < E_{G}) | −19 |
| Net power available after absorption | 49 |
| Voltage and fill factor losses | −19 (approximate) |
| Practical power limit | 30 |

The use of materials for wavelength conversion is known in the prior art. FIG. 4 shows a solar cell investigated by Bryce and Shalav (“Enhancing the near-infra-red Spectral response of silicon optoelectronic devices via up-conversion,” IEEE Trans on Electron Devices Vol. 54, p. 2679, 2007). At the heart of this device is a solar cell variation of the type shown n FIG. 1 comprising an absorbing material 50 made from silicon, front collection grid 53 and front antireflection (AR) coating 54 upon which lights rays 51 are incident. The back contact has been modified with a back collection grid 57 and back AR coating 55 so that photons can be transmitted between the absorber 50 and emulsion 59. In this prior art device, the emulsion 59 contains a plurality of suspended crystals 60 comprising Er-doped NaYF₄ which is known to absorb infra-red photons and emit visible photons. Infra-red photons transmitted to the emulsion are absorbed and re-emitted. The re-emitted photons are transmitted to the solar cell absorbing material 50 directly, or by reflection from a silver back surface mirror 56. In this way, this prior art device overcomes a small degree of non-absorption loss. The use of a down conversion material is also known in the prior art. Trupke, Green, and Wurfel (J. Appl. Phys. Vol. 92, p. 1668, 2002) have discussed down conversion layers applied to either the back or front of solar cells. These authors also mention the use of appropriate impurities in III-V compounds.

### SUMMARY

Exemplary embodiments of the present invention provide absorption, separation and re-emission of photons in solar cell glass covers, adhesive layers, or coatings applied to the solar cell. The inventive absorption, separation and re-emission processes enable the conversion of photon energy to overcome thermalization and nonabsorption losses, and thereby improve the conversion efficiency of the underlying solar cell. Exemplary embodiments of the invention provide conversion efficiency improvement by using materials that provide the absorption, separation and emission processes.

Exemplary embodiments of the invention are directed to a first set of semiconductors that have optical properties tuned during crystal formation, by variation of composition, to select a set of desired broad-band absorption properties, combined with a second set of semiconductors that can be selected to provide narrow band emission. This is possible because semiconductors permit long range (e.g., 500 to 5000 nm) electron transport, meaning that an absorbing layer can be located apart from the emitting layer, thus removing a constraint on the coupling of the two materials. This can be referred to as separation of the absorbing and emitting materials.

In one aspect of the invention, a photon conversion device comprises: a first layer for photon absorption, and a second layer for photon emission wherein the first layer is separate from the second layer, wherein the first and second layers enable excited electrons and holes to move from the first layer to the second layer and recombine in the second layer.

The photon conversion device can include one or more of the following features: a solar cell wherein at least a portion of the photons emitted by the second layer are absorbed by the solar cell, the first layer comprises a semiconductor, the first layer comprises a dielectric, the first and/or second layer comprises a semiconductor, the first and/or second layer comprises a dielectric, the second layer is doped with rare earth elements, the first and/or second layer is doped with rare earth elements, the first and/or second layers comprise multi-quantum well structures, the first and second layers are separated by a transport layer, the first and second layers are encapsulated between transparent materials, the transparent materials are optical elements, and the optical elements provide optical concentration.

In another aspect of the invention, a photon conversion system comprises: a photon down-conversion device, a photon up-conversion device, and a solar cell, wherein at least a portion of photons emitted by the up conversion device and a portion of photons emitted by the down conversion device are absorbable by the solar cell.

The photon conversion system can further include one or more of the following features: the photon down-conversion device, the photon up-conversion device, and the solar cell comprising stacked layers that are optically coupled, an optical cover, and the optical cover is a concentrating optical element.

In a further aspect of the invention, a method comprises absorbing photons in first layer, and emitting photons in a second layer, which is separate from the second layer, wherein the first and second layers enable excited electrons and holes to move from the first layer to the second layer and recombine in the second layer.

The method can further include absorbing at least a portion of photons emitted by the second layer by a solar cell.

### BRIEF DESCRIPTION OF THE DRAWINGS

The foregoing features of this invention, as well as the invention itself, may be more fully understood from the following description of the drawings in which:

FIG. 1 is a schematic representation of a prior art silicon solar cell;

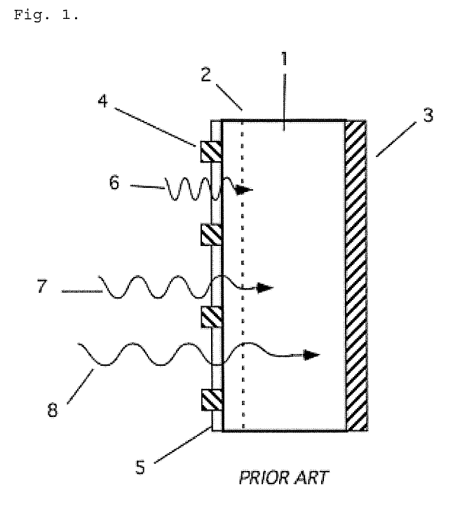

FIG. 2 is an energy band diagram of a prior art silicon solar cell showing allowed bands and energy band gap, where the abscissa is a distance from the front surface upon which light is incident and the ordinate is energy and also showing non-absorption loss;

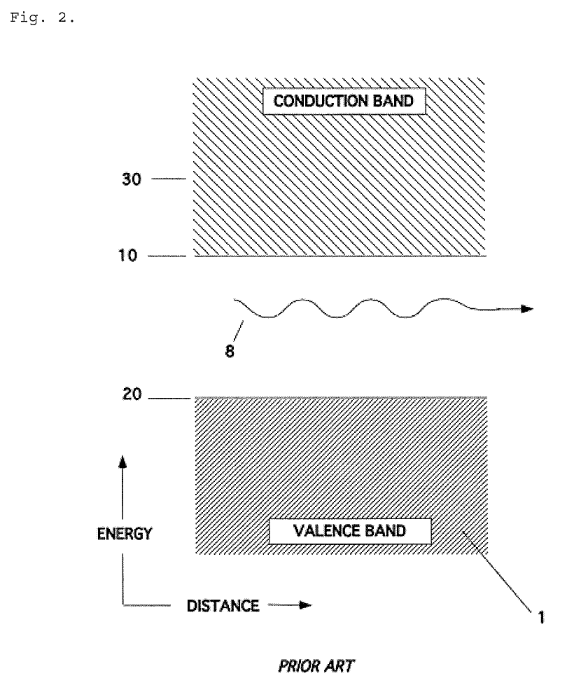

FIG. 3 is an energy band diagram illustrating thermalization energy loss;

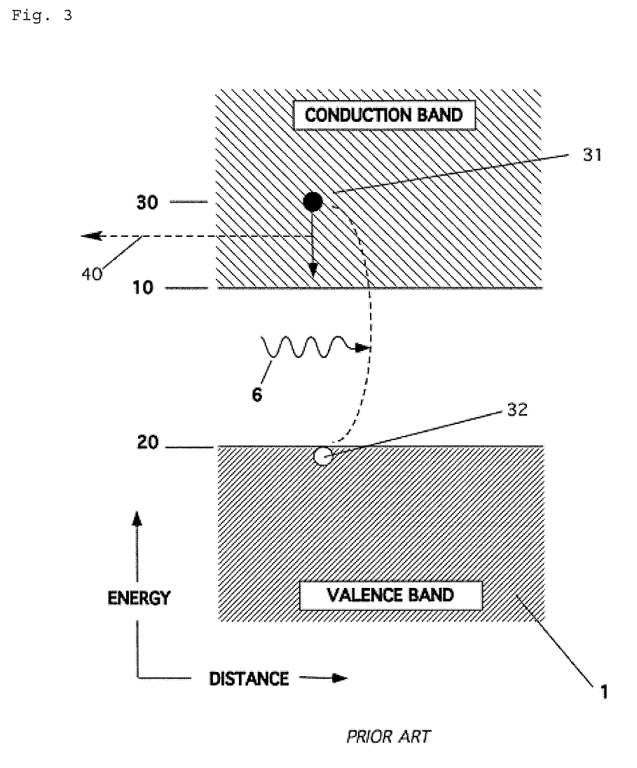

FIG. 4 is a schematic representation of a prior art silicon solar cell with an up conversion layer on back surface;

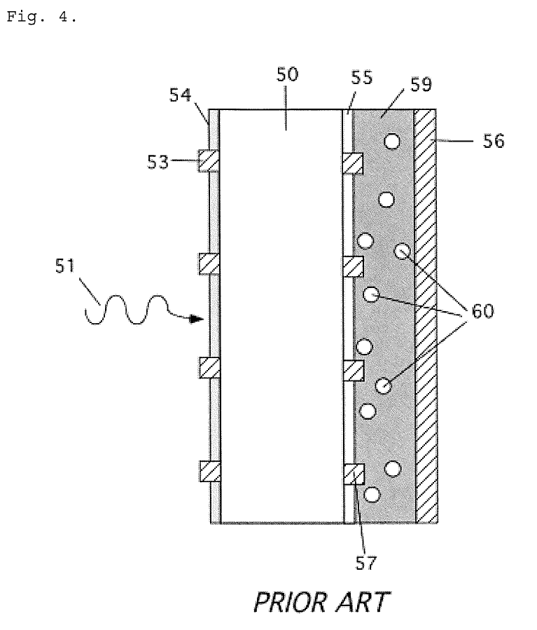

FIG. 5 is a schematic representation of a conversion device in accordance with exemplary embodiments of the invention;

FIG. 5A shows an energy band diagram for an exemplary material comprising a semiconductor having a conduction band minimum energy and a valence band minimum energy, where the semiconductor is also doped with rare earth or other dopants;

FIG. 6 is a schematic representation showing further details of conversion layers in the conversion device of FIG. 5;

FIG. 7 is an energy band diagram corresponding to the conversion layers of FIG. 6;

FIG. 8 is a diagram of three stages of electron hole motion: FIG. 8a shows an e-h pair diffusing to the vicinity of rare earth ions, FIG. 8b shows the capture of the pair by the rare earth ion, and FIG. 8c depicts a cooperative non-radiative process resulting in two excited e-h pairs;

FIG. 9 is an energy band diagram of an up conversion process in a semiconductor;

FIG. 10 is an energy band diagram of an up conversion process separating absorption and emission;

FIG. 11 is a energy band diagram of up conversion process using non-radiative cross relaxation;

FIG. 12 is an energy band diagram of cross relaxation up conversion process in a layer between the absorber and emitter.

FIG. 13 is a schematic representation of a multi-quantum well up converter layer;

FIG. 14 is an energy band diagram for a multi-quantum well up converter;

FIG. 15 is a schematic diagram of up and down conversion integrated in a device; and

FIG. 16 is a schematic representation of an exemplary solar cell with an up and down conversion device in the secondary optical element.

### DETAILED DESCRIPTION

Many single semiconductor and multiple semiconductor combinations have been used to create solar cells. While exemplary embodiments of the invention are primarily shown and described as silicon solar cells, it is understood that embodiments of the invention are applicable to a wide variety of solar cells, as well as energy conversion devices that are not photovoltaic solar cells.

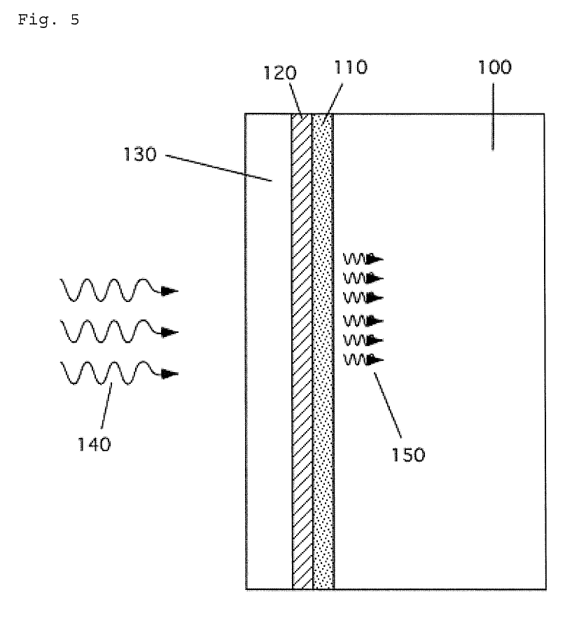

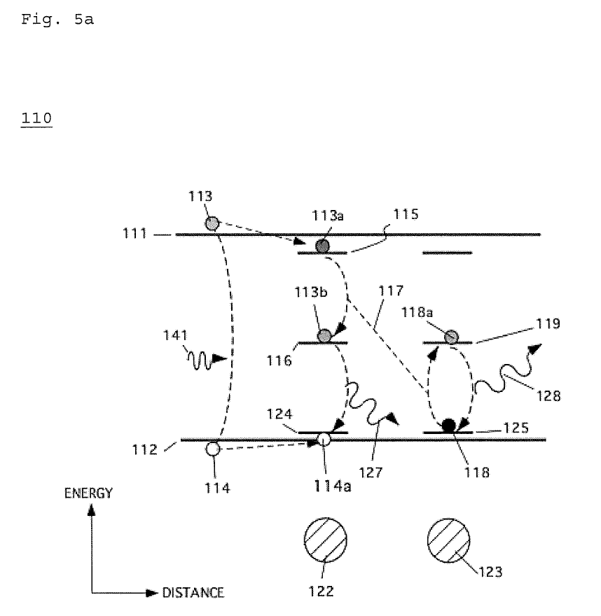

FIG. 5 shows a solar cell 100 provided with coatings 110 deposited on the solar cell in accordance with exemplary embodiments of the invention. An adhesive 120, such as ethylene vinyl acetate, is used to fix the cell to glass 130. The glass 130 may be a coverglass or may be the glass plate of the solar cell module. Layers 110 comprise materials that provide up and/or down conversion. Alternatively, materials that provide spectrum modification may be placed in or on the glass 130, or within the adhesive 120.

Solar photons 140 pass through layers 130, 120 and 110 and are modified in number and wavelength by absorption and re-emission. Energy emerges from these layers in the form of photons 150 and radiates into the solar cell 100, and propagates in a plurality of directions. An example is shown in FIG. 5a in which material 110 comprises a semiconductor having a conduction band minimum energy 111 and a valence band minimum energy 112, which semiconductor is also doped in at least one region with rare earth or other dopants 122, 123. A solar photon 141 is absorbed by material 110 by exciting an electron 113 from the valence band to the conduction band, and also leaving a hole 114 in the valence band. The electron 113 is captured by a state 115 associated with dopant 122 (and the electron is now designated 113a). The electron 113a may relax to state 116 by contributing its energy to the promotion of an electron 118 associated with dopant 123 by a cross relaxation process 117. The result is an electron 113b in state 116 of dopant 122, and a second electron 118a in state 119 of dopant 123. The electrons in states 116 and 119 may relax to states 124 and 125 respectively, by emitting photons 127 and 128. The result of this process is that photon 141 is down-converted (in energy) to photons 127 and 128.

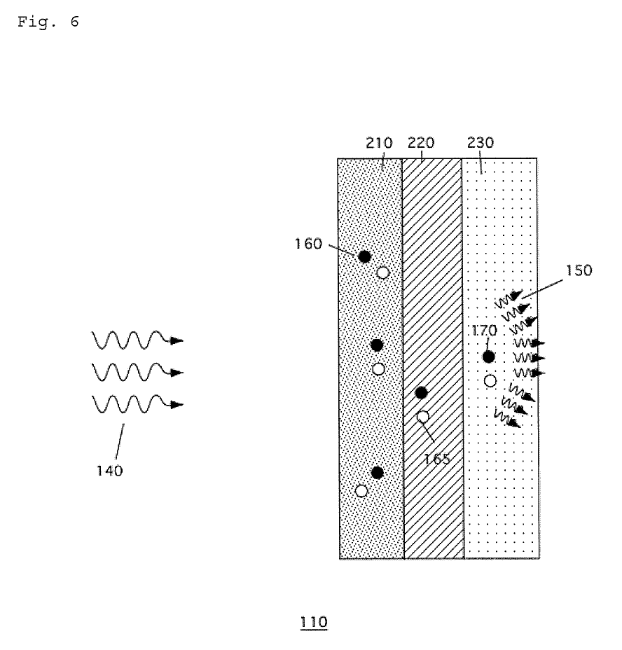

Material 110 may comprise separate layers of absorbing and emitting materials, as shown in FIG. 6. In this embodiment, layer 210 is a semiconductor absorber (such as GaₓIn_{y}N for example) in which the composition is chosen to select an absorption edge in the short wavelength visible region of the spectrum. Other semiconductors (such as for example GaₓIn_{y}P or ZnSeₓS_{y}) or other materials may be used. The absorption process creates e-h pairs 160 that diffuse to region 220. Region 220 may comprise a drift field to enhance transport of electrons and holes 165 to region 230. In this way, the electrons and holes 165 are separated from region 210 to minimize recombination. Region 230 may comprise a rare-earth-doped semiconductor, or a quantum well semiconductor, that provides radiative recombination via intermediate states, as described in detail below.

Region 220 may be thin (<100 nm) and may be in some cases absent. The purpose of region 220 is to enhance the separation of e-h pairs from the absorber 210. In some embodiments, region 220 is not needed as long as the absorber and emitter processes occur in different layers.

Region 230 may comprise a lattice doped with atoms that permits processes that change the energy and number of the electrons and holes. For example, region 230 may be a semiconductor such as GaₓIn_{y}P doped with rare earth ions that permit cooperative energy exchange or cross relaxation. Alternatively, region 230 may be a fluorinated crystal such as BaY₂F₈ doped with rare earth ions. A number of rare earth ions, including for example Er³⁺and Tm³⁺, are known to exhibit cooperative energy transfer in which an electron relaxes from an excited state by nonradiative transfer of some of its energy to an electron in a neighboring rare earth ion. The neighboring electron is excited to a higher energy state. In this way the energy from a single e-h pair may be distributed among two or more e-h pairs.

In one embodiment, the structure 110 reduces the thermalization loss by functioning as a down converting layer. Referring to FIG. 6, photons 140 are absorbed to create electron-hole pairs 160. Also shown is a pair 165 that has diffused to region 220 and a pair 170 that has been further transported to region 230 where it recombines radiatively via a multi-step process to create some of the photons 150.

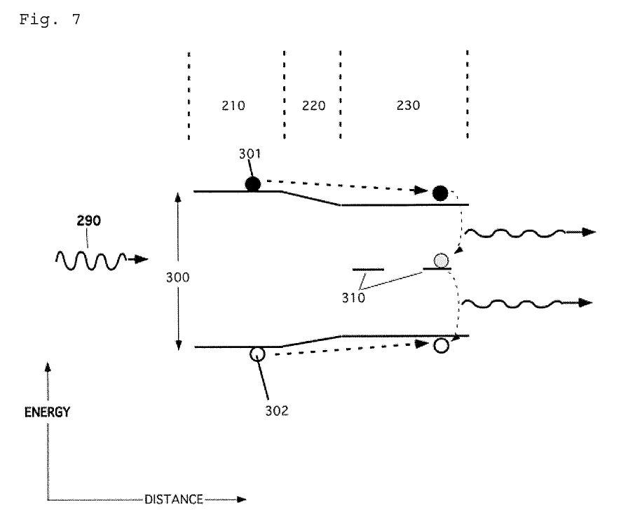

FIG. 7 is a representation of the simplified energy band diagram of one such device. For application to silicon solar cells, the band gap 300 of the absorber may be 2.4 eV. The layer 210, which may have a thickness of between 100 nm and 5,000 nm, absorbs an incident photon 290 that has energy greater than the band gap 300, leading to an excited electron 301 and hole 302 pair. This e-h pair diffuses in region 210 until crossing the interface between region 210 and 220. Once in region 220, the decreasing band gap assists in the transport of the pair to region 230.

Region 230 is doped with radiative recombination centers 310 that enable the electron-hole pair to recombine in first and second steps by emission of two photons. If the recombination center 310 has an energy state at the center of the band gap, two photons of energy E/2 are produced, where E is the energy band gap of region 230. These photons are radiated isotropically; one half will propagate toward the solar cell. Most of the radiation propagating away from the solar cell will undergo total internal reflection and will eventually reach the solar cell.

Referring again to FIG. 7, the incoming photon 290 having energy of approximately the band gap of material 210 is absorbed to create an electron 301 and hole 302 pair in material 210, and the pair diffuses and or drifts to material 230, where the pair recombines by one of the previously described processes, thereby emitting two photons each with energy of slightly less than one half of the band gap of material 230. In this way, one input photon is converted to two output photons.

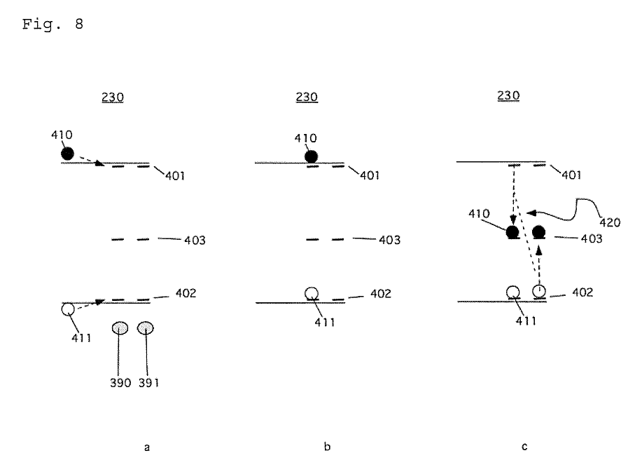

The recombination centers 310 may be states associated with rare earth dopants such as Er³⁺or Tm³⁺or other dopants which undergo cross relaxation processes. FIGS. 8 a, b, and c illustrate three of the steps in a cross relaxation process which occurs in a cross relaxation region comprising material doped with rare earth ions. In this example, the dopant atoms 390, 391 and the material 230 are chosen so that one of the energy states 401 of the dopant lies approximately at the conduction band minimum energy, and another state of the ion lies at the valence band maximum energy 402, and a third state 403 is intermediate. FIG. 8a illustrates a material 230 in which two identical rare earth dopant atoms 390, 391, are located within 10 nm of each other. Each dopant atom has associated with it at least three states 401, 402 and 403, where level 402 is occupied by an electron and level 401 and 403 are not occupied by electrons. An e-h pair may diffuse to the vicinity of the dopant 390, and the electron 410 may then be captured by and occupy level 401, and the hole may be captured and occupy level 402. In other words, the electron in state 402 drops into the hole in the valence band. In this process, some energy may be transferred to phonons in order to satisfy energy and momentum conservation. In the resultant configuration, the dopant 390 has an electron in an excited state, as shown in FIG. 8b. In this region, nearby rare earth dopants are known to undergo a cross relaxation process which is shown schematically in FIG. 8c. In this process, electron 410 relaxes to state 403 of atom 390 and contributes its energy through a nonradiative transfer process 420 to an electron in state 402 of atom 391, thus exciting the electron to state 403 of atom 391. The energy previously stored in the e-h pair in FIG. 8b, less any energy provided to phonons, is now stored in the mid-band gap excited states 403 of atoms 390 and 391. These excited electrons may recombine radiatively, thus producing two photons of approximately one half the band gap energy. Alternatively, these electrons may be further transferred non-radiatively to other dopants that may then relax by radiating photons.

The reverse process can also be attained using cross relaxation. In such a process, two photons excite two electrons from states 402 to states 403. Through cross relaxation, a single electron is elevated to state 401. The electron is further elevated to the conduction band by a small amount of thermal energy provided by a phonon.

It is understood that a variety of materials are suitable candidates for layers 210, 220 and 230. Wide band gap semiconductors such as GaN, GaP or related compounds such as GaₓIn₁₋ₓP_{y}N_{1-y} can be adjusted in composition to match the energy levels of selected rare earth or other dopants. Materials such as Si₃N₄, SiO₂, ZnO, or many oxides, nitrides, insulators or other semiconductors may be used. The dopants may be added during material deposition or ion-implanted into the layers. Many dopants may be used, including the rare earth dopants such as for example Er³⁺.

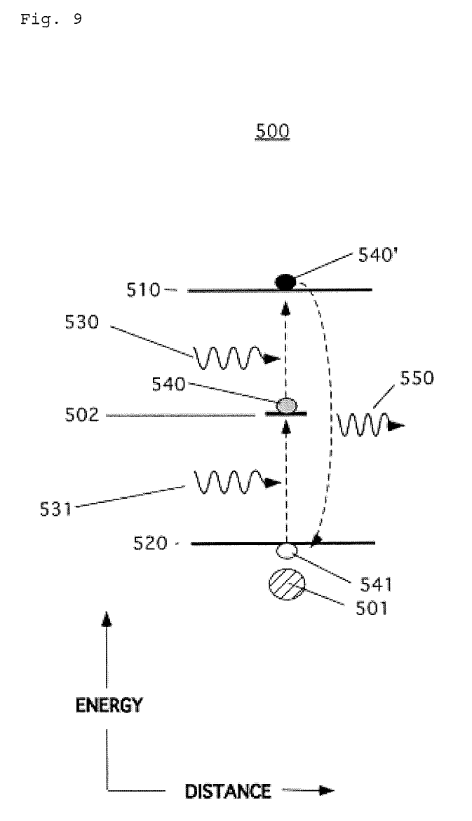

The addition of two photons to form a single photon of larger energy is shown in FIG. 9, in which a semiconductor 500 is doped with an atom 501 that has a mid-band gap state 502. An electron 540 at the valence band maximum energy 520 is elevated to state 502 by absorption of photon 531, and is shown as electron 540′ (while in state 502). After absorption of the second photon 530, the electron is in the conduction band and is indicated as 540″. The excited electron leaves a hole 541 in the valence band. This process can result in the emission of the desired photon 550, or the re-emission of photons 530, 531.

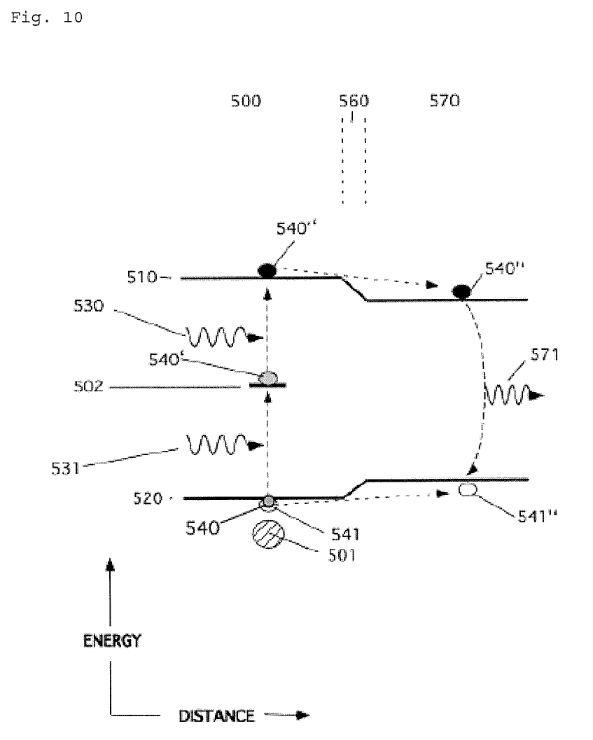

The efficiency of the process can be improved by separating the absorption and emission, as shown in FIG. 10. In this case, the e-h pairs are transported through layer 560 to material 570 and are shown as 540″, 541″. Material 570 does not have dopant atoms 501; therefore the only radiative recombination path is the emission of photon 571.

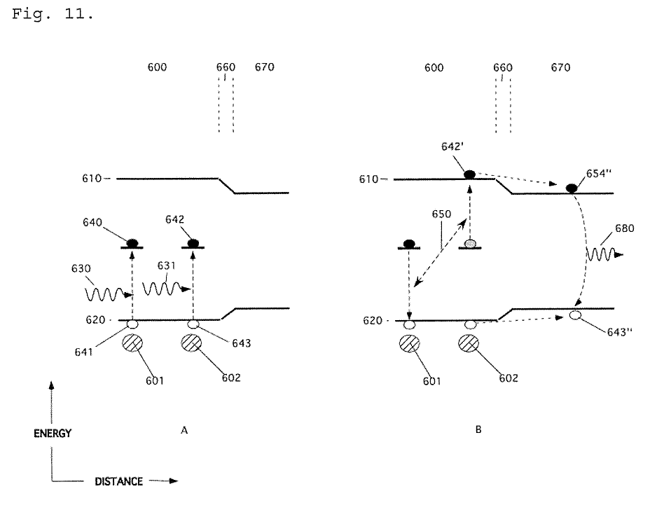

The up-conversion process can utilize non-radiative energy transfer as shown in FIG. 11. Referring to FIG. 11a, in this embodiment, a material 600 is doped with impurities 601, 602 which may be rare earth ions such as for example Er³⁺. Photon 630 is absorbed by ion 601 and photon 631 is absorbed by ion 602. FIG. 11b shows an Auger process in which electron 642 is excited to the conduction band minimum energy 610, by accepting energy from electron 640 which returns electron 640 to its ground state. The excited electron 642′ can now undergo transport through layer 660 to layer 670 where it recombines to produce photon 680.

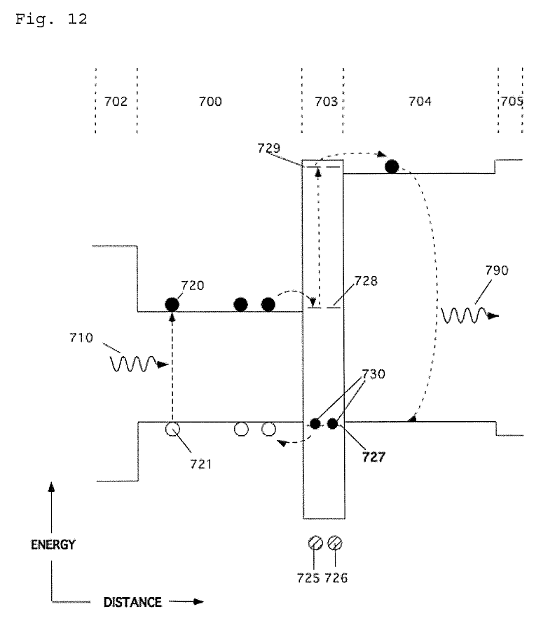

FIG. 12 illustrates another embodiment in which photons 710 are absorbed in material 700. A heteroface is formed using material 702 to minimize front surface recombination in a manner well known in the art. The absorption of photon 710 creates an excited electron 720 and hole 721. E-h pairs excited in this way diffuse to an intermediate layer 703 which may be a semiconductor having an energy band gap slightly larger than the energy of the desired emitted photons. For example, the material 703 could be Al_{0.1}Ga_{0.9}As and the semiconductor 704 could be GaAs. Material 703 is doped with rare earth ions 725, 726 that may for example be Er³⁺to form a cross relaxation region. Levels 728 of ions 725, 726 are populated by electrons that reach the interface between 700 and 703, and then tunnel into the states by well-known quantum mechanical tunneling processes. A cross relaxation process previously described excites one of these electrons to state 729. The electron may be thermionically emitted into the conduction band of 703, or it may tunnel into the conduction band of material 704. Material 704 may also have a heteroface structure by use of layer 705 so as to minimize back surface recombination. Photon 790 is emitted by radiative band-to-band recombination. The structure in FIG. 12 may be seen to have as a feature the separation of absorption, up-conversion, and emission.

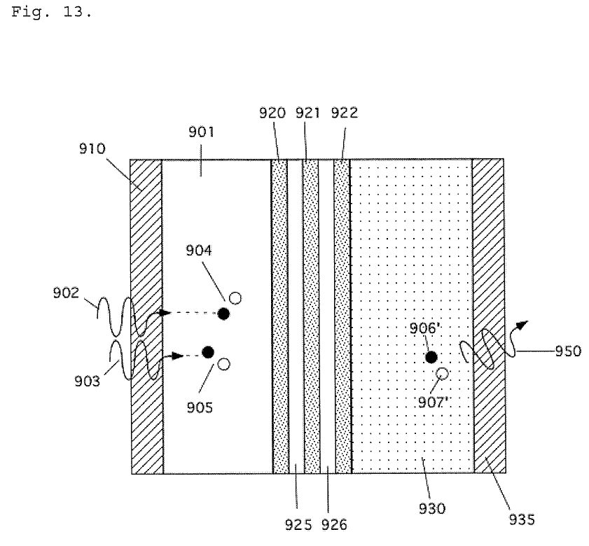

In an alternate embodiment of the invention, quantum wells are used instead of dopant atoms to provide radiative recombination paths in a cross relaxation region. FIG. 13 illustrates a structure that up-converts input photons 902, 903 to an output photon 950. The absorption and conversion of photons 902, 903 to e-h pairs 904, 905 occurs in material 901, which is chosen for the particular spectral absorption range of interest. For example, germanium may be used for up-conversion of wavelengths in the infrared that are not absorbed by gallium arsenide. Material 910, which may be aluminum gallium arsenide, can be used to create a heteroface structure that reduces the front surface recombination velocity. Layers 925, 926 are made thin (having thickness 938, 939 between about 1 and 10 nm) to as to provide quantum mechanical confinement known to produce discrete energy levels. The material is selected to provide energy states needed for up conversion; one possible material is gallium arsenide. Any suitable semiconductor may be used that provides sufficient radiative recombination.

Layers 920, 921 and 922 are wide band gap materials, such as aluminum gallium arsenide, that serve to confine the carriers in materials 925, 926 so as to form quantum wells. While this example shows two quantum wells, any number of wells may be provided in a laminate structure. Electrons 906′ and holes 907′ may recombine in the quantum wells or in an adjacent material 930 to produce an output photon 950. Quantum wells of reduced dimension (quantum dots) may also be used to form a cross relaxation region. The material 930 may comprise gallium arsenide or any III-V alloy that provides radiative recombination, such as semiconductors with direct energy band gaps. The surface recombination velocity on the back surface may be reduced by providing a wide band gap heteroface layer 935.

Structures of the type shown in FIG. 13 may be placed on the front or back of the solar cell. If used as an up-converter on the back, then one of the surfaces would be optically coupled to a back surface mirror, and the other would be coupled to a solar cell, in a manner well known to one of ordinary skill in the art.

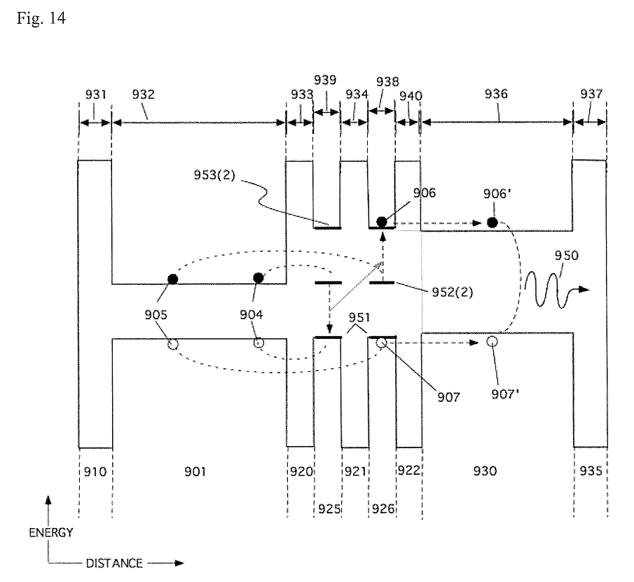

The up-conversion of photons can be further understood by reference to FIG. 14, which is a simplified energy band diagram corresponding to the structure shown in FIG. 13. Photons are incident on the heteroface structure 910, which may have a thickness 931 in the range of 5 nm to 100 nm, pass through layer 910 and are absorbed in layer 901, thus creating e-h pairs 904, 905. The optimal thickness 932 of layer 901 will depend on the absorption rate in the particular material, and the ambipolar diffusion length for e-h pairs. The e-h pairs diffuse through material 901 until reaching layer 920. The respective thicknesses 933, 934, 940 of layers 920, 921, 922 are in the range of about 1 to 5 nm, thus permitting quantum mechanical tunneling through these layers. Quantum confinement in layers 925 and 926 produces discrete energy states 951, 952 and 953. Electron-hole pairs 904, 905 can thus tunnel to and occupy states 952 and 951 respectively. Non-radiative cross relaxation as previously described can elevate one electron to a state 953 and relax one electron to a state 951 (in other words, one electron recombines with a hole, yielding its energy to the excitation of the other electron). The excited electron 906 in state 953 can recombine with the hole in state 951 to produce output photon 950, or both can tunnel to the bands in material 930 and can recombine radiatively to produce photon 950. The thickness 936 of material 930 may be in the range of 50 to 500 nm.

Although in FIG. 13 we have shown an up-converter, it should be recognized that the device principles described here can be used to make either an up converter or down converter, or can be combined to make an integrated up and down converter.

It is understood that a variety of fabrication methods can be used to provide the converters. Converters may be grown using epitaxial techniques and the rare earth or other radiative recombination centers can be added as dopants. Alternatively, the materials can be doped by diffusion or ion implantation. A further alternative comprises the formation of nanoparticles having two domains: one for absorption and one for emission, provided the processes are separated by a carrier transport region that inhibits recombination as has been described.

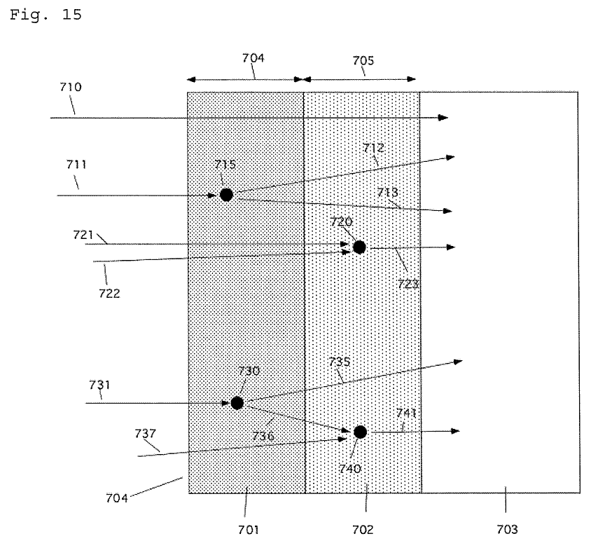

FIG. 15 shown an exemplary integrated up and down converter. Light is incident on the surface 704 of a down-converting layer 701 which is optically coupled to an up converting layer 702, which is in turn optically coupled to a solar cell 703. In this device, a photon 710 may pass directly to the solar cell without absorption; whether this occurs depends in part on the thickness 704 of the up converter and the thickness 705 of the down converter and the absorption constants for the particular materials. Photon 711 illustrates the down conversion by a site 715 which may comprise one or more rare earth ions or quantum wells, as has previously been described. The output of the down conversion process comprises two photons 712, 713 that may be absorbed by the solar cell. For example, if the solar cell is silicon, and the initial ray has an input wavelength of 400 nm, the output wavelengths of photons 712 and 713 will be at least 800 nm; however, any output wavelengths shorter than 1110 nm can be absorbed by silicon, thus increasing the photo-generated current. Thus, even if some energy is lost to heat or other photons, the process still provides a net increase in solar cell current.

Photons 721, 722 in FIG. 15 illustrate the up conversion at site 720 in layer 702. The output photon 723 may be absorbed by the solar cell 703. For example, if the solar cell is silicon, and the input photons have wavelength of 1300 nm, the photons would not be absorbed by a conventional silicon solar cell. However, the up-conversion process may produce one photon having a wavelength as short as 650 nm, which can be absorbed by silicon. The output photon need only have a wavelength shorter than about 1110 nm, meaning that some energy can be lost to heat or other photons and the process will still improve the photo-generated current in the solar cell.

Referring to FIG. 15, the regions 701 and 702 may comprise semiconductors doped with rare earth ions or multi-quantum wells, s has been previously described. Alternatively, regions 701 and 702 may each be a plurality of layers in which absorption and emission are separated.

The integration of up and down conversion provides a means to recover photons that might otherwise be lost in the conversion process. This is shown by photon 731 which is absorbed by site 730, and which produces two photons. The first is photon 735 which can be absorbed by solar cell 703. The second is photon 736, which in this example has a wavelength that is too long for absorption in the solar cell. However, if photon 736 can participate in up conversion at site 740, it may be combined with photon 737 to produce photon 741 which can be absorbed. Thus, in an integrated up/down converter, the photon input to the up conversion process can comprise either solar photons such as 721, 722, and 737, as well as photons generated by down conversion, such as photon 736. It should be evident that if the up conversion process yields output photons that are sufficiently short in wavelength, the down converter layer can shift the wavelength back to the desired range. Thus, the up and down converter layers can be designed to work synergistically to improve the photo-generated current in the solar cell.

The depictions in this specification have shown the photons propagating toward the solar cell. However, as previously described, the emission process is isotropic. It should be understood that the emitted photons will largely be trapped by the high index of refraction of the materials so that ultimately most of the photons will reach the solar cell. The isotropic emission also means that at least one half of the photons emitted by the up converter 702 will be incident on the down converter 701, meaning that the optics enables the process previously described that synergistically down converts energetic up-converted photons arriving from the up converter.

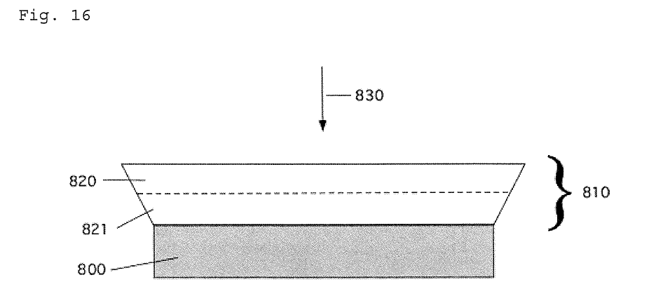

FIG. 16 shows how the up and down conversion layers may be integrated in an optical device for a concentrator solar cell 800. In this example, the up conversion layer 821 and the down conversion layer 820 can be combined in a secondary optical element 810. The layers that have been previously described can be laminated onto the front and/or back of the element, or can be made integrally with the element by blending the rare earth ions, quantum wells or other particles with the material of element 810.

Having described exemplary embodiments of the invention, it will now become apparent to one of ordinary skill in the art that other embodiments incorporating their concepts may also be used. The embodiments contained herein should not be limited to disclosed embodiments but rather should be limited only by the spirit and scope of the appended claims. All publications and references cited herein are expressly incorporated herein by reference in their entirety.

What is claimed is:

1. A photon conversion device comprising:
a first layer for photon absorption; and
a second layer for photon emission wherein the first layer is separate from the second layer,
wherein the first and second layers enable excited electrons and holes to move from the first layer to the second layer and recombine in the second layer.

2. The device of claim 1, further comprising a solar cell wherein at least a portion of the photons emitted by the second layer are absorbed by the solar cell.

3. The device of claim 1 wherein the first layer comprises a semiconductor.

4. The device of claim 1, wherein the first layer comprises a dielectric.

5. The device of claim 1, wherein the first and/or second layer comprises a semiconductor.

6. The device of claim 1, wherein the first and/or second layer comprises a dielectric.

7. The device of claim 1 wherein the second layer is doped with rare earth elements.

8. The device of claim 1, wherein the first and/or second layer is doped with rare earth elements.

9. The device of claim 1, wherein the first and/or second layers comprise multi-quantum well structures.

10. The device of claim 1, wherein the first and second layers are separated by a transport layer.

11. The device of claim 1, wherein the first and second layers are encapsulated between transparent materials.

12. The device of claim 1, further including a third layer disposed between the first and second layers, wherein the third layer includes a cross relaxation region.

13. The device of claim 11, wherein the transparent materials are optical elements.

14. The device of claim 13, wherein the optical elements provide optical concentration.

15. A photon conversion system comprising:
a photon down-conversion device;
a photon up-conversion device; and
a solar cell,
wherein at least a portion of photons emitted by the up conversion device and a portion of photons emitted by the down conversion device are absorbable by the solar cell.

16. The system of claim 15, wherein the photon down-conversion device, the photon up-conversion device, and the solar cell comprise stacked layers that are optically coupled.

17. The system of claim 15, further comprising an optical cover.

18. The system of claim 17, wherein the optical cover is a concentrating optical element.

19. A method, comprising:
absorbing photons in first layer; and
emitting photons in a second layer, which is separate from the second layer,
wherein the first and second layers enable excited electrons and holes to move from the first layer to the second layer and recombine in the second layer.

20. The method according to claim 19, further including absorbing at least a portion of photons emitted by the second layer by a solar cell.

21. A photon conversion device comprising:
a semiconductor configured to absorb a portion of the solar spectrum by creating electron-hole pairs, and
at least one dopant disposed within the semiconductor, wherein the electron-hole pairs recombine at the dopant thereby emitting photons.

22. The device of claim 21, wherein at least one of the dopants is a rare earth ion.

23. The device of claim 21, wherein the dopants form a cross relaxation region.
